(19) United States
(12) Patent Application Publication
(10) Pub. No.: US 2026/0251970 A1
(43) Pub. Date: Aug. 27, 2026

(54) PHOTOSENSITIVE RESIN COMPOSITION, PHOTOSENSITIVE ELEMENT, METHOD FOR FORMING RESIST PATTERN, AND METHOD FOR PRODUCING CIRCUIT BOARD

(71) Applicant: Resonac Corporation, Tokyo (JP)

(72) Inventors: Naoki HIRAMATSU, Tokyo (JP); Keishi ONO, Tokyo (JP); Mao NARITA, Tokyo (JP); Shiho TANAKA, Tokyo (JP)

(21) Appl. No.: 18/859,886

(22) PCT Filed: Feb. 20, 2024
(86) PCT No.: PCT/JP2024/006110

§ 371 Date: Oct. 24, 2024

(30) Foreign Application Priority Data
Mar. 17, 2023 (WO) PCT/JP2023/010670

(51) Int. Cl. G03F 7/004; G03F 7/028; G03F 7/32; H05K 3/06; H05K 3/18

(52) U.S. Cl. CPC G03F 7/0048; G03F 7/028; G03F 7/322; H05K 3/06; H05K 3/18

(57) ABSTRACT

A photosensitive resin composition contains a binder polymer, a photopolymerizable compound, a photopolymerization initiator, and a solvent, in which the solvent contains at least one selected from the group consisting of a ketone-based solvent having an alicyclic skeleton and an aromatic ether-based solvent.

### TECHNICAL FIELD

The present disclosure relates to a photosensitive resin composition, a photosensitive element, a method for forming a resist pattern, and a method for producing a circuit board.

### BACKGROUND ART

In the manufacture of circuit boards, resist patterns are formed to obtain desired circuit. For formation of resist patterns, photosensitive resin compositions are widely used. Photosensitive resin compositions can be prepared by dissolving components such as a binder polymer, a photopolymerizable compound, and a photopolymerization initiator in a solvent such as toluene (see, for example, Patent Literature 1).

### CITATION LIST

### Patent Literature

Patent Literature 1: WO 2007/004619

### SUMMARY OF INVENTION

### Technical Problem

Conventional photosensitive resin compositions may discolor after long-term storage, and therefore their storage stability is required to be improved. Accordingly, an object of the present disclosure is to provide a photosensitive resin composition and a photosensitive element of which discoloration after long-term storage can be suppressed, as well as a method for forming a resist pattern and a method for manufacturing a circuit board using these.

### Solution to Problem

The present inventors have conducted extensive studies to solve the above problems and discovered that discoloration of a photosensitive resin composition after long-term storage can be suppressed by using a specific organic solvent as the solvent used in the production of the photosensitive resin composition, and thus completed the present invention.

The present disclosure provides the following photosensitive resin composition, photosensitive element, method for forming a resist pattern, and method for manufacturing a circuit board.
[1] A photosensitive resin composition containing: a binder polymer, a photopolymerizable compound, a photopolymerization initiator, and a solvent, in which the solvent includes at least one selected from the group consisting of a ketone-based solvent having an alicyclic skeleton and an aromatic ether-based solvent.
[2] The photosensitive resin composition according to [1], in which the ketone-based solvent having an alicyclic skeleton includes at least one selected from the group consisting of cyclopentanone and cyclohexanone.
[3] The photosensitive resin composition according to [1], in which the aromatic ether-based solvent includes anisole.
[4] The photosensitive resin composition according to any one of [1] to [3], in which the solvent does not include toluene.
[5] A photosensitive element including: a support; and a photosensitive layer formed on the support using the photosensitive resin composition according to any one of [1] to [4].
[6] A method for forming a resist pattern, the method including: a step of forming a photosensitive layer on a substrate using the photosensitive resin composition according to any one of [1] to [4] or the photosensitive element according to [5]; a step of photocuring a portion of the photosensitive layer; and a step of removing an uncured portion of the photosensitive layer by development.
[7] The method for forming a resist pattern according to [6], in which an inorganic alkaline developer is used in the development.
[8] A method for manufacturing a circuit board, the method comprising a step of forming a conductor pattern by etching or plating a substrate on which a resist pattern is formed by the method for forming a resist pattern according to [6] or [7].

### Advantageous Effects of Invention

According to the present disclosure, it is possible to provide a photosensitive resin composition and a photosensitive element of which discoloration after long-term storage can be suppressed, as well as a method for forming a resist pattern and a method for manufacturing a circuit board using these. According to the present disclosure, since toluene, which is an environmentally regulated substance, does not need to be used as a solvent, it is possible to provide a photosensitive resin composition and a photosensitive element that are environmentally friendly, as well as a method for forming a resist pattern and a method for manufacturing a circuit board using these.

### BRIEF DESCRIPTION OF DRAWINGS

FIG. 1 is a schematic cross-sectional view illustrating a photosensitive element according to an embodiment.

FIG. 2 is a schematic cross-sectional view illustrating a method for manufacturing a circuit board according to an embodiment.

### DESCRIPTION OF EMBODIMENTS

Hereinafter, embodiments of the present disclosure will be described in detail.

In this specification, the term “step” includes not only an independent step, but also a step that cannot be clearly distinguished from another step as long as the intended action of the step is achieved. The numerical range indicated using “to” indicates a range that includes the numerical values before and after “to” as the minimum and maximum values, respectively. The term “layer” encompasses a structure having a shape formed on a part of a surface as well as a structure having a shape formed on the entire surface when observed in plan view. The term “(meth)acrylic acid” refers to at least either of “acrylic acid” or “methacrylic acid” corresponding thereto. The same applies to other similar expressions such as (meth)acrylate as well.

In this specification, the term “(poly)oxyethylene group” means an oxyethylene group or a polyoxyethylene group in which two or more ethylene groups are linked via an ether bond. The term “(poly)oxypropylene group” means an oxypropylene group or a polyoxypropylene group in which two or more propylene groups are linked via an ether bond. The term “EO-modified” means a compound having a (poly)oxyethylene group. The term “PO-modified” means a compound having a (poly)oxypropylene group. The term “EO/PO-modified”means a compound having a (poly)oxyethylene group and/or a (poly)oxypropylene group.

In this specification, in a case where a plurality of substances corresponding to each component are present in a composition, the amount of each component in the composition means the total amount of the plurality of substances present in the composition, unless otherwise specified. In this specification, the term “solids” refers to non-volatile components excluding volatile substances in the photosensitive resin composition. In other words, the term “solids” refers to components other than the solvent that do not volatilize during drying of the photosensitive resin composition to be described later but remain, and includes those that are liquid, syrup-like, or wax-like at room temperature (25° C.).

### <Photosensitive Resin Composition>

The photosensitive resin composition according to the present embodiment contains a binder polymer (hereinafter also referred to as “component (A)”), a photopolymerizable compound (hereinafter also referred to as “component (B)”), a photopolymerization initiator (hereinafter also referred to as “component (C)”), and a solvent (hereinafter also referred to as “component (D)”). Here, the component (D) includes at least one selected from the group consisting of a ketone-based solvent having an alicyclic skeleton and an aromatic ether-based solvent. Hereinafter, each component will be described.

### Component (A): Binder Polymer

The photosensitive resin composition contains one kind or two or more kinds of component (A). Examples of the component (A) include an acrylic resin, a styrene-based resin, an epoxy-based resin, an amide-based resin, an amide-epoxy-based resin, an alkyd-based resin, and a phenol-based resin.

From the viewpoint of alkali developability, the component (A) may include an acrylic resin. The acrylic resin is a resin having a structural unit (monomer unit) derived from a (meth)acryloyl group-containing compound.

The (meth)acryloyl group-containing compound is a compound that contains a (meth)acryloyl group. Examples of the (meth)acryloyl group-containing compound include a hydroxyalkyl (meth)acrylate, (meth)acrylic acid, a (meth)acrylic acid alkyl ester, a (meth)acrylic acid aryl ester, a (meth)acrylic acid cycloalkyl ester, acrylamides such as diacetone acrylamide, a (meth)acrylic acid tetrahydrofurfuryl ester, a (meth)acrylic acid dimethylaminoethyl ester, a (meth)acrylic acid diethylaminoethyl ester, (meth)acrylic acid glycidyl ester, 2,2,2-trifluoroethyl (meth)acrylate, 2,2,3,3-tetrafluoropropyl (meth)acrylate, α-bromoacrylic acid, α-chloroacrylic acid, β-furyl(meth)acrylic acid, and β-styryl(meth)acrylic acid.

The acrylic resin may be, for example, a polymer (a) having at least one selected from the group consisting of a hydroxyalkyl (meth)acrylate unit, a (meth)acrylic acid unit, a (meth)acrylic acid alkyl ester unit, and a (meth)acrylic acid aryl ester unit.

The hydroxyalkyl (meth)acrylate unit is a structural unit derived from a hydroxyalkyl (meth)acrylate. Examples of the hydroxyalkyl (meth)acrylate include hydroxymethyl (meth)acrylate, hydroxyethyl (meth)acrylate, hydroxypropyl (meth)acrylate, hydroxybutyl (meth)acrylate, hydroxypentyl (meth)acrylate, and hydroxyhexyl (meth)acrylate. In a case where the alkyl moiety in the hydroxyalkyl (meth)acrylate unit has 3 or more carbon atoms, the alkyl moiety may have a branched structure.

In a case where the polymer (a) has a hydroxyalkyl (meth)acrylate unit, based on the total amount of the monomer units constituting the polymer (a), the content of the hydroxyalkyl (meth)acrylate unit may be 0.5% by mass or more, 0.75% by mass or more, 1.0% by mass or more, 1.5% by mass or more, or 2.0% by mass or more from the viewpoint of dispersibility, or may be 20% by mass or less, 15% by mass or less, 8% by mass or less, 5% by mass or less, or 4% by mass or less from the viewpoint of water absorbing properties.

The (meth)acrylic acid unit is a structural unit derived from (meth)acrylic acid. In a case where the polymer (a) has a (meth)acrylic acid unit, based on the total amount of the monomer units constituting the polymer (a), the content of the (meth)acrylic acid unit may be 1% by mass or more, 5% by mass or more, 10% by mass or more, 15% by mass or more, 20% by mass or more, or 25% by mass or more, or may be 50% by mass or less, 45% by mass or less, 40% by mass or less, 35% by mass or less, or 30% by mass or less from the viewpoints of resolution and adhesiveness.

The (meth)acrylic acid alkyl ester unit is a structural unit derived from a (meth)acrylic acid alkyl ester. The alkyl group of the (meth)acrylic acid alkyl ester may be, for example, a methyl group, an ethyl group, a propyl group, a butyl group, a pentyl group, a hexyl group, a heptyl group, an octyl group, a nonyl group, a decyl group, an undecyl group, a dodecyl group, or a structural isomer thereof, or may be an alkyl group having 1 to 4 carbon atoms from the viewpoint of release property.

In a case where the polymer (a) has a (meth)acrylic acid alkyl ester unit, based on the total amount of the monomer units constituting the polymer (a), the content of the (meth)acrylic acid alkyl ester unit may be 1% by mass or more, 2% by mass or more, or 3% by mass or more from the viewpoint of release property, or may be 80% by mass or less, 60% by mass or less, or 50% by mass or less from the viewpoints of resolution and adhesiveness.

The (meth)acrylic acid aryl ester unit is a structural unit derived from a (meth)acrylic acid aryl ester. Examples of the (meth)acrylic acid aryl ester include benzyl (meth)acrylate, phenyl (meth)acrylate, and naphthyl (meth)acrylate. In a case where the polymer (a) has a (meth)acrylic acid aryl ester unit, based on the total amount of the monomer units constituting the polymer (a), the content of the (meth)acrylic acid aryl ester unit may be 1% by mass or more, 5% by mass or more, 10% by mass or more, 15% by mass or more, or 18% by mass or more or may be 50% by mass or less, 45% by mass or less, 40% by mass or less, 35% by mass or less, 30% by mass or less, 25% by mass or less, or 23% by mass or less from the viewpoints of resolution and adhesiveness.

The polymer (a) may further have a structural unit derived from a monomer other than the (meth)acryloyl group-containing compound. The other monomer may be one kind or two or more kinds.

Examples of the other monomer include styrene or a styrene derivative, acrylonitrile, vinyl alcohol ethers such as vinyl n-butyl ether, maleic acid, maleic anhydride, maleic acid monoesters such as monomethyl maleate, monoethyl maleate, and monoisopropyl maleate, fumaric acid, cinnamic acid, α-cyanocinnamic acid, itaconic acid, crotonic acid, and propiolic acid. Examples of the styrene derivative include vinyltoluene and α-methylstyrene.

In a case where the polymer (a) has a structural unit derived from styrene or a styrene derivative (hereinafter also referred to as a “styrene or styrene derivative unit”), based on the total amount of the monomer units constituting the polymer (a), the content of the styrene or styrene derivative unit may be 20% by mass or more, 30% by mass or more, 40% by mass or more, 45% by mass or more, 47% by mass or more, or 50% by mass or more from the viewpoint of resolution, or may be 90% by mass or less, 85% by mass or less, 80% by mass or less, 70% by mass or less, or 60% by mass or less from the viewpoint of developability.

The polymer (a) may be a polymer (al) having a hydroxyalkyl (meth)acrylate unit, a (meth)acrylic acid unit, a styrene or styrene derivative unit, and a (meth)acrylic acid aryl ester unit.

The component (A) may include a binder polymer other than the polymer (a), or may consist only of the polymer (a). From the viewpoints of adhesiveness and resolution, the content of the polymer (a) in the component (A) may be 50% to 100% by mass or may be 80% to 100% by mass based on the total amount of the component (A).

The acid value of the polymer (a) may be 100 mgKOH/g or more, 120 mgKOH/g or more, 140 mgKOH/g or more, or 150 mgKOH/g or more from the viewpoint of developability, or may be 250 mgKOH/g or less, 240 mgKOH/g or less, or 230 mgKOH/g or less from the viewpoint of adhesiveness (developer resistance) of the cured product of the photosensitive resin composition. The acid value of the polymer (a) can be adjusted by the content of structural units (for example, (meth)acrylic acid unit) constituting the polymer (a). In a case where the component (A) includes a binder polymer other than the polymer (a), the acid value of the other binder polymer may also be within the above range.

The weight average molecular weight (Mw) of polymer (a) may be 10000 or more, 15000 or more, 20000 or more, 25000 or more, or 30000 or more from the viewpoint of adhesiveness (developer resistance) of the cured product of the photosensitive resin composition, or may be 100000 or less, 80000 or less, 60000 or less, or 40000 or less from the viewpoint of developability. The dispersity (Mw/Mn) of the polymer (a) may be, for example, 1.0 or more, or 1.5 or more, or may be 3.0 or less or 2.5 or less from the viewpoints of adhesiveness and resolution. In a case where the component (A) includes a binder polymer other than the polymer (a), the Mw of the other binder polymer may also be within the above range.

The weight average molecular weight and the dispersity can be measured, for example, by gel permeation chromatography (GPC) using a calibration curve of standard polystyrene. More specifically, the weight average molecular weight and the dispersity can be measured under conditions described in Examples. In a case where it is difficult to measure the weight average molecular weight of compounds having low molecular weights using the above-mentioned method, it is also possible to measure the molecular weights by other methods and calculate the average thereof.

The content of the component (A) may be 20% by mass or more, 30% by mass or more, or 40% by mass or more from the viewpoint of film formability or may be 90% by mass or less, 80% by mass or less, 70% by mass or less, or 65% by mass or less from the viewpoints of sensitivity and resolution based on the total solid amount in the photosensitive resin composition.

The content of the component (A) may be 30 parts by mass or more, 35 parts by mass or more, or 40 parts by mass or more from the viewpoint of film formability or may be 70 parts by mass or less, 65 parts by mass or less, or 60 parts by mass or less from the viewpoints of sensitivity and resolution based on 100 parts by mass of the total amount of the components (A) and (B).

Component (B): Photopolymerizable compound

The photosensitive resin composition contains one kind or two or more kinds of component (B). The component (B) is only required to be a compound that is polymerized by light, and may be, for example, a compound having an ethylenically unsaturated bond. The component (B) may include a polyfunctional monomer having two or more reactive groups that react with radicals. From the viewpoints of alkali developability, resolution, and release property after curing, the component (B) may include a bisphenol A type (meth)acrylate compound.

Examples of the bisphenol A type (meth)acrylate compound include 2,2-bis(4-((meth)acryloxypolyethoxy)phenyl)propane, 2,2-bis(4-((meth)acryloxypolypropoxy)phenyl)propane, 2,2-bis(4-((meth)acryloxypolybutoxy)phenyl)propane, and 2,2-bis(4-((meth)acryloxypolyethoxypolypropoxy)phenyl) propane. From the viewpoints of resolution and release property, the component (B) may include 2,2-bis(4-((meth)acryloxypolyethoxy)phenyl)propane. Examples of the 2,2-bis(4-((meth)acryloxypolyethoxy)phenyl)propane include 2,2-bis(4-((meth)acryloxypentaethoxy)phenyl)propane. As the 2,2-bis(4-((meth)acryloxypolyethoxy)phenyl)propane, a compound having 10 or more oxyethylene groups may be used, a compound having less than 10 oxyethylene groups may be used, or a compound having 10 or more oxyethylene groups and a compound having less than 10 oxyethylene groups may be used together.

In a case where the component (B) includes a bisphenol A type (meth)acrylate compound, the content of the bisphenol A type (meth)acrylate compound may be 20% by mass or more, 40% by mass or more, 60% by mass or more, 80% by mass or more, 85% by mass or more, or 90% by mass or more or may be 100% by mass or less or 95% by mass or less based on the total amount of the component (B) from the viewpoint of resist resolution.

From the viewpoints of resolution and flexibility, the component (B) may include an α,β-unsaturated ester compound obtained by reacting a polyhydric alcohol with an α,β-unsaturated carboxylic acid. Examples of the α,β-unsaturated ester compound include polyalkylene glycol di(meth)acrylates such as polyethylene glycol di(meth)acrylate, polypropylene glycol di(meth)acrylate, and EO-modified polypropylene glycol di(meth)acrylate, trimethylolpropane di(meth)acrylate, trimethylolpropane tri(meth)acrylate, EO-modified trimethylolpropane tri(meth)acrylate, PO-modified trimethylolpropane tri(meth)acrylate, EO/PO-modified trimethylolpropane tri(meth)acrylate, tetramethylolmethane tri(meth)acrylate, and tetramethylolmethane tetra(meth)acrylate.

From the viewpoints of sensitivity and adhesiveness, the component (B) may include a compound having three or more (meth)acryloyl groups. Examples of such a compound include trimethylolpropane tri(meth)acrylate, EO-modified trimethylolpropane tri(meth)acrylate, PO-modified trimethylolpropane tri(meth)acrylate, EO/PO-modified trimethylolpropane tri(meth)acrylate, EO-modified pentaerythritol tetra(meth)acrylate, EO-modified ditrimethylolpropane tetra(meth)acrylate, and EO-modified dipentaerythritol hexa (meth)acrylate.

In a case where the component (B) includes an α,β-unsaturated ester compound, based on the total amount of the component (B), the content of the α,β-unsaturated ester compound may be 1% by mass or more, 3% by mass or more, 5% by mass or more, or 8% by mass or more from the viewpoint of flexibility, or may be 20% by mass or less, 15% by mass or less, or 10% by mass or less from the viewpoint of resolution.

The photosensitive resin composition may contain a photopolymerizable compound other than the bisphenol A type (meth)acrylate compound and α,β-unsaturated ester compound as the component (B).

Examples of the other photopolymerizable compound include nonylphenoxy polyethyleneoxy acrylate, a phthalic acid-based compound, a (meth)acrylic acid alkyl ester, and a photopolymerizable compound having at least one cationic polymerizable cyclic ether group in the molecule (an oxetane compound or the like). The other photopolymerizable compound may be at least one selected from the group consisting of nonylphenoxy polyethyleneoxy acrylate and a phthalic acid-based compound from the viewpoints of resolution, adhesiveness, resist shape, and release property after curing.

Examples of the nonylphenoxy polyethyleneoxy acrylate include nonylphenoxy triethyleneoxy acrylate, nonylphenoxy tetraethyleneoxy acrylate, nonylphenoxy pentaethyleneoxy acrylate, nonylphenoxy hexaethyleneoxy acrylate, nonylphenoxy heptaethyleneoxy acrylate, nonylphenoxy octaethyleneoxy acrylate, nonylphenoxy nonaethyleneoxy acrylate, nonylphenoxy decaethyleneoxy acrylate, and nonylphenoxy undecaethyleneoxy acrylate.

Examples of the phthalic acid-based compound include γ-chloro-β-hydroxypropyl-β′-(meth)acryloyloxyethyl-o-phthalate (also known as 3-chloro-2-hydroxypropyl-2-(meth)acryloyloxyethyl phthalate), β-hydroxyethyl-β′-(meth)acryloyloxyethyl-o-phthalate, and β-hydroxypropyl-β′-(meth)acryloyloxyethyl-o-phthalate.

In a case where the component (B) contains the other photopolymerizable compound, the content of the other photopolymerizable compound may be 1% by mass or more, 3% by mass or more, or 5% by mass or more or may be 30% by mass or less, 25% by mass or less, or 20% by mass or less based on the total amount of the component (B) from the viewpoints of resolution, adhesiveness, resist shape, and release property after curing.

Among the compounds described above, the component (B) may include a compound having a total of 2 to 40 oxyethylene groups (EO groups) and/or oxypropylene groups (PO groups) in the molecule from the viewpoints of adhesiveness and resolution. The total number of EO groups and/or PO groups may be 2 to 40 or 2 to 30 from the viewpoints of adhesiveness and resolution.

The component (B) may include a compound having a urethane group. Examples of the compound having a urethane group include a compound having 1 to 3 urethane groups in the molecule. The compound having a urethane group does not need to include a compound having 4 or more urethane groups in the molecule.

The content of the component (B) may be 3% by mass or more, 10% by mass or more, or 25% by mass or more from the viewpoints of sensitivity and resolution or may be 70% by mass or less, 60% by mass or less, or 50% by mass or less from the viewpoint of film formability based on the total solid amount in the photosensitive resin composition.

### Component (C): Photopolymerization Initiator

The photosensitive resin composition contains one kind or two or more kinds of component (C). Examples of the component (C) include a hexaarylbiimidazole compound; oxime ester compounds such as 1,2-octanedione-1-[4-(phenylthio)phenyl]-2-(o-benzoyloxime), 1-[9-ethyl-6-(2-methylbenzoyl)-9H-carbazol-3-yl]ethanone 1-(o-acetyloxime), and 1-phenyl-1,2-propanedione-2-[o-(ethoxycarbonyl) oxime]; aromatic ketones such as benzophenone, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-butanone, 4-(2-hydroxyethoxy)phenyl-2-(hydroxy-2-propyl)ketone, and 2-methyl-1-[4-(methylthio)phenyl]-2-morpholino-propanone-1; quinones such as an alkylanthraquinone; benzoin ether compounds such as a benzoin alkyl ether; benzoin compounds such as benzoin and an alkylbenzoin; benzil derivatives such as benzil dimethyl ketal; bis(2,4,6-trimethylbenzoyl)-phenylphosphine oxide; bis(2,6-dimethylbenzoyl)-2,4,4-trimethyl-pentylphosphine oxide; and (2,4,6-trimethylbenzoyl)ethoxyphenylphosphine oxide.

The component (C) may include at least one selected from the group consisting of a hexaarylbiimidazole compound and an oxime ester compound, or may include a hexaarylbiimidazole compound. The aryl group in the hexaarylbiimidazole compound may be a phenyl group or the like. A hydrogen atom bonded to the aryl group in the hexaarylbiimidazole compound may be substituted with a halogen atom (a chlorine atom or the like) or an alkoxy group (a methoxy group or the like).

The hexaarylbiimidazole compound may be a 2,4,5-triarylimidazole dimer. Examples of the 2,4,5-triarylimidazole dimer include 2-(o-chlorophenyl)-4,5-diphenylimidazole dimer, 2-(o-chlorophenyl)-4,5-bis-(m-methoxyphenyl) imidazole dimer, and 2-(p-methoxyphenyl)-4,5-diphenylimidazole dimer.

From the viewpoints of sensitivity and adhesiveness, the content of the component (C) may be 0.1 parts by mass or more, 0.5 parts by mass or more, 1 part by mass or more, 3 parts by mass or more, 5 parts by mass or more, 6 parts by mass or more, 7 parts by mass or more, or 7.5 parts by mass or more or may be 20 parts by mass or less, 15 parts by mass or less, 10 parts by mass or less, 9 parts by mass or less, or 8.5 parts by mass or less with respect to 100 parts by mass of the total amount of the components (A) and (B).

### Component (D): Solvent

The photosensitive resin composition contains one kind or two or more kinds of component (D). The component (D) includes at least one selected from the group consisting of a ketone-based solvent having an alicyclic skeleton (hereinafter also referred to as “component (d1)”) and an aromatic ether-based solvent (hereinafter also referred to as “component (d2)”). By using such components (d1) and (d2) as the component (D), discoloration of the photosensitive resin composition after long-term storage can be suppressed.

The components (d1) and (d2) can achieve solubility equal to or greater than that of toluene, which has been conventionally used in the preparation of photosensitive resin compositions, and appropriate viscosity and therefore can be used as alternative solvents to toluene. Since the component (D) does not need to include toluene, an environmentally friendly photosensitive resin composition can be prepared.

Examples of the component (d1) include cyclopentanone and cyclohexanone. Examples of the component (d2) include anisole.

From the viewpoint of achieving superior discoloration suppressing properties, the component (D) preferably includes at least one selected from the group consisting of cyclopentanone, cyclohexanone, and anisole, and more preferably includes at least one selected from the group consisting of cyclopentanone and cyclohexanone.

The component (d1) can improve the solubility of components (for example, the component (C)) other than the component (D) contained in the photosensitive resin composition, and therefore may be used singly. By using the component (d1), the number of kinds of solvents can be decreased, and this is advantageous in terms of environmental friendliness and workability.

The component (D) may include another solvent as long as the effects of the present disclosure are not impaired. Examples of the other solvent include methanol and acetone.

The content of the component (D) may be 20 parts by mass or more or 30 parts by mass or more or may be 70 parts by mass or less, 60 parts by mass or less, 50 parts by mass or less, or 40 parts by mass or less with respect to 100 parts by mass of the total amount of the components (A) and (B).

In a case where the component (D) includes the component (d1), the content of the component (d1) may be 10 parts by mass or more, 20 parts by mass or more, 25 parts by mass or more, 30 parts by mass or more, or 35 parts by mass or more or may be 70 parts by mass or less, 60 parts by mass or less, 50 parts by mass or less, or 40 parts by mass or less with respect to 100 parts by mass of the total amount of the components (A) and (B). In a case where the component (D) includes the component (d1), the content of the component (d1) may be 50% by mass or more, 60% by mass or more, 70% by mass or more, 80% by mass or more, 90% by mass or more, or 100% by mass based on the total amount of the (D) component. In a case where the component (D) includes the component (d1), the content of the component (d1) may be 2.5 times or more, 3.0 times or more, 3.5 times or more, 4.0 times or more, or 4.5 times or more the content of the component (C).

In a case where the component (D) includes the component (d2), the content of the (d2) component may be 10 parts by mass or more, 15 parts by mass or more, or 20 parts by mass or more or may be 70 parts by mass or less, 60 parts by mass or less, 50 parts by mass or less, 40 parts by mass or less, or 30 parts by mass or less with respect to 100 parts by mass of the total amount of the components (A) and (B). In a case where the component (D) includes the component (d2), the content of the component (d2) may be 40% by mass or more, 45% by mass or more, 50% by mass or more, or 55% by mass or more or may be 70% by mass or less or 60% by mass or less based on the total amount of the (D) component. In a case where the component (D) includes the component (d2), the content of the component (d2) may be 2.5 times or more, 3.0 times or more, 3.5 times or more, 4.0 times or more, or 4.5 times or more the content of the component (C).

### Component (E): Photosensitizer

The photosensitive resin composition may further contain a photosensitizer as a component (E). The component (E) is not particularly limited, and any known photosensitizer can be used. Examples of the component (E) include an anthracene-based sensitizer. Examples of the anthracene-based sensitizer include 9,10-dibutoxyanthracene, 9,10-diphenylanthracene, and 9,10-diethoxyanthracene. From the viewpoints of adhesiveness and resolution, the anthracene-based sensitizer may be 9,10-dibutoxyanthracene.

In a case where the photosensitive resin composition contains the component (E), with respect to 100 parts by mass of the total amount of the components (A) and (B), the content of the component (E) may be 0.2 parts by mass or more, 0.3 parts by mass or more, 0.4 parts by mass or more, or 0.5 parts by mass or more from the viewpoints of sensitivity, adhesiveness, and resolution, or may be 1.5 parts by mass or less, 1.0 part by mass or less, 0.8 parts by mass or less, 0.75 parts by mass or less, or 0.7 parts by mass or less from the viewpoint of resist pattern shape.

### Component (F): Polymerization Inhibitor

The photosensitive resin composition may further contain a polymerization inhibitor as a component (F). Examples of the polymerization inhibitor include t-butylcatechol and 4-hydroxy-2,2,6,6-tetramethylpiperidine-N-oxyl.

In a case where the photosensitive resin composition contains the component (F), with respect to 100 parts by mass of the total amount of the components (A) and (B), the content of the component (F) may be 0.001 parts by mass or more, 0.005 parts by mass or more, 0.008 parts by mass or more, 0.01 parts by mass or more, or 0.015 parts by mass or more from the viewpoints of sensitivity and resolution, or may be 0.1 parts by mass or less, 0.05 parts by mass or less, or 0.03 parts by mass or less from the viewpoints of sensitivity and adhesiveness.

### Component (G): Dye

The photosensitive resin composition may further contain a dye as a component (G). The component (G) is not particularly limited, and any known dye can be used. Examples of the component (G) include Leuco dyes, Phthalocyanine Green, Crystal Violet, Methyl Orange, Nile Blue 2B, Victoria Blue, Malachite Green, Basic Blue 20, and Diamond Green. Examples of the Leuco dyes include Leuco Crystal Violet and Fluoran dyes.

In a case where the photosensitive resin composition contains the component (G), the content of the component (G) may be 0.01 parts by mass or more, 0.05 parts by mass or more, 0.10 parts by mass or more, 0.20 parts by mass or more, 0.30 parts by mass or more, 0.40 parts by mass or more, or 0.50 parts by mass or more or may be 20 parts by mass or less, 10 parts by mass or less, 5 parts by mass or less, or 1 part by mass or less with respect to 100 parts by mass of the total amount of the components (A) and (B).

The photosensitive resin composition may further contain one kind or two or more kinds of components other than the components described above. Examples of the other components include a hydrogen donor (bis [4-(dimethylamino)phenyl]methane, bis[4-(diethylamino)phenyl]methane, N-phenylglycine, or the like), tribromophenyl sulfone, a thermal coloring inhibitor, a plasticizer (p-toluenesulfonamide, or the like), a pigment, a filler, a defoamer, a flame retardant, a stabilizer, an adhesiveness imparting agent, a leveling agent, a release promoter, an antioxidant, a fragrance, an imaging agent, and a thermal crosslinker. The content of the other components may be 0.005 parts by mass or more, or 0.01 parts by mass or more or may be 20 parts by mass or less with respect to 100 parts by mass of the total amount of the components (A) and (B).

The photosensitive resin composition can be suitably used in a method for forming a resist pattern and a method for manufacturing a circuit board, which will be described later.

### <Photosensitive Element>

The photosensitive element according to the present embodiment includes a support and a photosensitive layer formed on the support using the above-described photosensitive resin composition. The photosensitive element may further include a protective layer on the photosensitive layer.

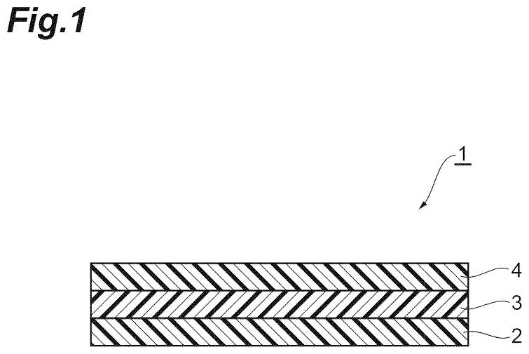

FIG. 1 is a schematic cross-sectional view illustrating a photosensitive element according to an embodiment. As illustrated in FIG. 1, a photosensitive element 1 includes a support 2, a photosensitive layer 3 provided on the support 2, and a protective layer 4 provided on the side opposite to the support 2 of the photosensitive layer 3.

As the support, a polymer film exhibiting heat resistance and solvent resistance can be used. Examples of the support include polyester films such as a polyethylene terephthalate film, a polybutylene terephthalate film, and a polyethylene-2,6-naphthalate film; and polyolefin films such as a polyethylene film and a polypropylene film.

The haze of the support may be 0.01% to 5.0%, 0.01% to 1.5%, 0.01% to 1.0%, or 0.01% to 0.5%. The haze can be measured using a commercially available haze meter (turbidity meter) in conformity with the method specified in JIS K7105. Haze can be measured, for example, using a commercially available turbidity meter such as NDH-5000 (trade name, manufactured by NIPPON DENSHOKU INDUSTRIES CO., LTD.).

The thickness of the support may be 1 μm or more, 5 μm or more, or 10 μm or more from the viewpoint of easily suppressing damage to the support when the support is peeled off from the photosensitive layer. The thickness of the support may be 100 μm or less, 50 μm or less, 30 μm or less, or 20 μm or less from the viewpoint of facilitating suitable exposure in a case of performing exposure via the support.

The protective layer may be a polymer film exhibiting heat resistance and solvent resistance, and for example, polyolefin films such as a polyethylene film and a polypropylene film can be used. In particular, as a polyethylene film is used as a protective layer, the winding displacement of the photosensitive element can be suppressed and static electricity is unlikely to be generated when the protective layer is peeled off from the photosensitive layer, and therefore damage to the photosensitive layer can be suppressed.

From the viewpoint of easily suppressing damage to the protective layer when the photosensitive layer and the support are laminated on the substrate while the protective layer is peeled off, the thickness of the protective layer may be 1 μm or more, 5 μm or more, 10 μm or more, or 15 μm or more. From the viewpoint of easily improving productivity, the thickness of the protective layer may be 100 μm or less, 50 μm or less, 40 μm or less, or 30 μm or less.

The photosensitive layer is formed using the photosensitive resin composition described above. The thickness of the photosensitive layer after drying (after the solvent has been evaporated) may be 1 μm or more, 5 μm or more, 10 μm or more, or 15 μm or more from the viewpoints of facilitating coating and improving productivity, or may be 100 μm or less, 50 μm or less, 40 μm or less, or 30 μm or less from the viewpoints of adhesiveness and resolution.

The photosensitive element 1 can be obtained, for example, as follows. First, the photosensitive layer 3 is formed on the support 2. The photosensitive layer 3 can be formed, for example, by applying a photosensitive resin composition to form a coating layer and drying this coating layer. Next, the protective layer 4 is formed on the surface opposite to the support 2 of the photosensitive layer 3.

The coating layer is formed by, for example, a known method such as roll coating, comma coating, gravure coating, air knife coating, die coating, or bar coating. Drying of the coating layer is performed so that the amount of the solvent remaining in the photosensitive layer 3 is, for example, 2% by mass or less, and is specifically performed, for example, at 70 to 150° C. for about 5 to 30 minutes.

In another embodiment, the photosensitive element may further include other layers, such as a cushion layer, an adhesive layer, a light absorbing layer, and a gas barrier layer.

The photosensitive element 1 may be, for example, in the form of a sheet, or in the form of a photosensitive element roll wound in a roll shape around a core. In the photosensitive element roll, the photosensitive element 1 is preferably wound with the support 2 on the outside. The core is formed of, for example, polyethylene, polypropylene, polystyrene, polyvinyl chloride, or an acrylonitrile-butadiene-styrene copolymer. An end face separator may be provided on the end face of the photosensitive element roll from the viewpoint of protecting the end face, or a moisture-proof end separator may be provided on the end face from the viewpoint of resistance to edge fusion. The photosensitive element 1 may be wrapped in, for example, a black sheet exhibiting low moisture permeability.

The photosensitive element according to the present embodiment can be suitably used in a method for forming a resist pattern and a method for manufacturing a circuit board, which will be described later.

### <Method for Forming Resist Pattern>

The method for forming a resist pattern according to the present embodiment includes a step of forming a photosensitive layer on a substrate using the photosensitive resin composition or the photosensitive element (hereinafter also referred to as the “photosensitive layer forming step”), a step of photocuring a portion of the photosensitive layer (hereinafter also referred to as the “exposure step”), and a step of removing the uncured portion of the photosensitive layer by development (hereinafter also referred to as the “development step”), and may further include other steps if necessary. The resist pattern can also be referred to as a photocured product pattern of a photosensitive resin composition or a relief pattern.

### (Photosensitive Layer Forming Step)

In the photosensitive layer forming step, a photosensitive layer is formed on a substrate using a photosensitive resin composition or a photosensitive element. The substrate is not particularly limited, but is usually a substrate for circuit formation having an insulating layer and a conductor layer formed on the insulating layer, a die pad (base material for lead frame) such as an alloy base material, or the like is used.

As the method for forming a photosensitive layer on a substrate, for example, by removing the protective layer from a photosensitive element and then pressure-bonding the photosensitive layer of the photosensitive element to the substrate while performing heating, the photosensitive layer can be formed on the substrate. By this, a laminate including a substrate, a photosensitive layer, and a support in this order is obtained.

The photosensitive layer forming step may be carried out under reduced pressure from the viewpoints of adhesiveness and followability. Heating during pressure bonding may be performed at a temperature of 70 to 130° C., and pressure bonding may be performed at a pressure of 0.1 to 1.0 MPa (1 to 10 kgf/cm²), but these conditions can be appropriately selected as necessary. It is not necessary to perform preheat treatment on the substrate in advance if the photosensitive layer of the photosensitive element is heated to 70 to 130° C., but the substrate may be subjected to a preheat treatment in order to further improve the adhesiveness and followability.

### (Exposure Step)

In the exposure step, the photosensitive layer may be exposed to actinic light via the support, or the support may be peeled off and then the photosensitive layer may be exposed to actinic light. By this, the exposed portion irradiated with the actinic light is photocured, and a photocured portion (latent image) is formed.

As the exposure method, a known exposure method can be applied, and examples thereof include a method in which an image is irradiated with actinic light via a negative or positive mask pattern called artwork (mask exposure method), an LDI (laser direct imaging) exposure method, and a method in which an image is irradiated with actinic light onto which a photomask is projected via a lens (projection exposure method). Among these, from the viewpoint of resolution, the LDI exposure method or the projection exposure method may be used. The projection exposure method can also be referred to as an exposure method using actinic light with attenuated energy amount.

The light source of actinic light is not particularly limited as long as it is a known light source that is commonly used, and for example, a light source, such as a carbon arc lamp, a mercury vapor arc lamp, an ultra-high pressure mercury lamp, a high pressure mercury lamp, a xenon lamp, gas lasers such as an argon laser, solid-state lasers such as a YAG laser, or semiconductor lasers such as a gallium nitride-based blue-violet laser, that effectively emits ultraviolet light is used. Among these, from the viewpoint of improving resolution and alignment properties in a well-balanced manner, a light source capable of emitting monochromatic i-line light having an exposure wavelength of 365 nm, a light source capable of emitting monochromatic h-line light having an exposure wavelength of 405 nm, or a light source capable of emitting actinic light having an exposure wavelength of ihg crossed lines may be used, or a light source capable of emitting monochromatic i-line light having an exposure wavelength of 365 nm or monochromatic h-line light having an exposure wavelength of 405 nm may be used. Examples of the light source capable of emitting monochromatic i-line light having an exposure wavelength of 365 nm include an ultra-high pressure mercury lamp. Examples of the light source capable of emitting monochromatic h-line light having an exposure wavelength of 405 nm include a blue-violet laser diode having a wavelength of 405 nm.

In the method for forming a resist pattern according to the present embodiment, post exposure bake (PEB) may be performed after the exposure step and before the development step from the viewpoint of adhesiveness. The temperature in a case of performing PEB may be 50 to 100° C. Heating may be performed using a heater such as a hot plate, a box-type dryer, or a heating roll.

### (Development Step)

In the development step, the uncured portion of the photosensitive layer is removed from the substrate. In a case where the photosensitive layer is exposed via the support, the support and the uncured portion of the photosensitive layer are removed from the substrate. By the development step, a resist pattern consisting of a photocured portion of the photosensitive layer subjected to photocuring is formed on the substrate. The development method may be wet development or dry development, and is preferably wet development.

In the case of wet development, development can be performed by a known wet development method using a developer suitable for the photosensitive resin composition. Examples of the wet development method include a dipping method, a paddle method, a high-pressure spraying method, and methods using brushing, scrubbing, and rocking immersion. These wet development methods may be used singly or in combination of two or more kinds thereof for development.

The developer is appropriately selected depending on the composition of the photosensitive resin composition, and may be, for example, an alkaline developer or an organic solvent developer.

From the viewpoints of safety, stability, and favorable operability, an alkaline developer may be used as the developer. The alkaline developer may be an aqueous solution containing a base such as alkali hydroxides such as hydroxides of lithium, sodium or potassium; alkali carbonates such as carbonates or bicarbonates of lithium, sodium, potassium or ammonium; alkali metal phosphates such as potassium phosphate and sodium phosphate; alkali metal pyrophosphates such as sodium pyrophosphate and potassium pyrophosphate; borax; sodium metasilicate; tetramethylammonium hydroxide; ethanolamine; ethylenediamine; diethylenetriamine; 2-amino-2-hydroxymethyl-1,3-propanediol; 1,3-diamino-2-propanol; or morpholine.

From the viewpoint of environmental friendliness, an inorganic alkaline developer may be used. As the inorganic alkaline developer, a 0.1% to 5% by mass dilute solution of sodium carbonate, a 0.1% to 5% by mass dilute solution of potassium carbonate, a 0.1% to 5% by mass dilute solution of sodium hydroxide, or a 0.1% to 5% by mass dilute solution of sodium tetraborate can be used.

The pH of the alkaline developer used for development may be in a range of 9 to 11, and the temperature of the alkaline developer can be adjusted according to the developability of the photosensitive layer. In the alkaline developer, for example, a surfactant, a defoamer, and a small amount of an organic solvent for accelerating development may be contained together. Examples of the organic solvent used in the alkaline developer include 3-acetone alcohol, acetone, ethyl acetate, alkoxyethanol having an alkoxy group having 1 to 4 carbon atoms, ethyl alcohol, isopropyl alcohol, butyl alcohol, diethylene glycol monomethyl ether, diethylene glycol monoethyl ether, and diethylene glycol monobutyl ether.

Examples of the organic solvent used in the organic solvent developer include 1,1,1-trichloroethane, N-methyl-2-pyrrolidone, N,N-dimethylformamide, cyclohexanone, methyl isobutyl ketone, and γ-butyrolactone. From the viewpoint of preventing ignition, organic solvent developers may be prepared by adding water to these organic solvents so that the concentration is in a range of 1% to 20% by mass.

### (Other Steps)

The method for forming a resist pattern according to the present embodiment may include a step of further curing the resist pattern by performing heating at 60 to 250° C. or exposure at an exposure of 0.2 to 10 J/cm², if necessary, after the uncured portion is removed in the development step.

### <Method for Manufacturing Circuit Board>

The method for manufacturing a circuit board according to the present embodiment includes a step of forming a conductor pattern (circuit layer) by etching or plating the substrate on which a resist pattern is formed by the method for forming a resist pattern described above, and may include other steps such as a resist pattern removing step, if necessary.

In the etching process, a resist pattern formed on a substrate including a conductor layer is used as a mask to remove the conductor layer of the substrate that is not covered with the resist by etching, thereby forming a conductor pattern.

The method of the etching process is appropriately selected depending on the conductor layer to be removed. Examples of the etching solution include a cupric chloride solution, a ferric chloride solution, an alkaline etching solution, and a hydrogen peroxide-based etching solution. From the viewpoint of a favorable etch factor, a ferric chloride solution may be used as the etching solution.

In the plating process, a resist pattern formed on a substrate including a conductor layer is used as a mask to plate copper, solder or the like on the conductor layer of the substrate that is not covered with the resist. After the plating process, the resist is removed by removing the resist pattern, which will be described later, and further the conductor layer covered with this resist is etched to form a conductor pattern.

The method of the plating process may be an electrolytic plating process or an electroless plating process, and examples thereof include copper plating such as copper sulfate plating and copper pyrophosphate plating, solder plating such as high throw solder plating, nickel plating such as Watts bath (nickel sulfate-nickel chloride) plating and nickel sulfamate plating, and gold plating such as hard gold plating and soft gold plating.

After the etching process or plating process, the resist pattern on the substrate is removed. For removal of the resist pattern, for example, peeling off can be performed using an aqueous solution that is more strongly alkaline than the alkaline developer used in the development step. As this strongly alkaline aqueous solution, for example, a 1% to 10% by mass aqueous sodium hydroxide solution and a 1% to 10% by aqueous potassium hydroxide solution are used. Among these, a 1% to 5% by mass aqueous solution of sodium hydroxide or potassium hydroxide may be used.

Examples of the method for removing the resist pattern include an immersion method and a spraying method, and these may be used singly or together.

In a case where the resist pattern is removed after a plating process is performed, the conductor layer covered with the resist can be further etched by an etching process to form a conductor pattern, thereby manufacturing a desired circuit board. The method of the etching process at this time is appropriately selected depending on the conductor layer to be removed. For example, the above-mentioned etching solution can be applied.

The method for manufacturing a circuit board according to the present embodiment can be applied to the manufacture of not only a single-layer circuit board but also a multi-layer circuit board, and can also be applied to the manufacture of a circuit board having through holes with a small diameter, and the like.

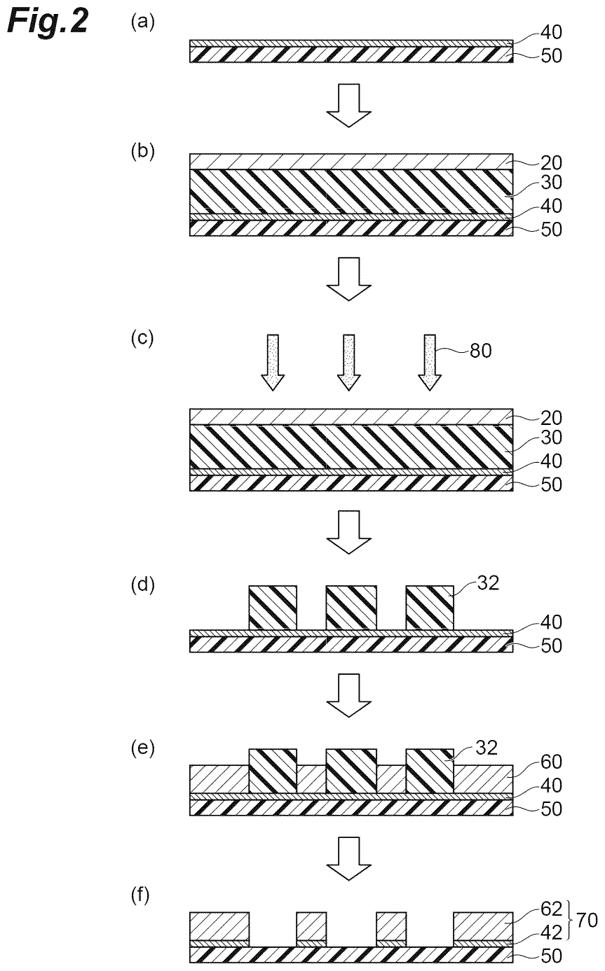

The method for manufacturing a circuit board according to the present embodiment can be suitably used for manufacturing high-density package substrates, in particular, for manufacturing circuit boards by a semi-additive process. An example of a process of manufacturing a circuit board by a semi-additive process is illustrated in FIG. 2.

In (a) of FIG. 2, a substrate (substrate for circuit formation) in which a conductor layer 40 is formed on an insulating layer 50 is prepared. The conductor layer 40 is, for example, a copper layer. In (b) of FIG. 2, a photosensitive layer 30 and a support 20 are formed on the conductor layer 40 of the substrate by the photosensitive layer forming step. In (c) of FIG. 2, by the exposure step, the photosensitive layer 30 is irradiated with actinic light 80 onto which an image of a photomask is projected via the support 20 to form a photocured portion in the photosensitive layer 30. In (d) of FIG. 2, by the development step, the regions other than the photocured portion formed by the exposure step are removed from the substrate to form a resist pattern 32 that is the photocured portion on the substrate.

In (e) of FIG. 2, a plating process is performed using the resist pattern 32 that is the photocured portion as a mask to form a plating layer 60 on the conductor layer 40 of the substrate that is not covered with the resist. The materials of the conductor layer 40 and the plating layer 60 may be the same as or different from each other. In a case where the materials of the conductor layer 40 and the plating layer 60 are the same as each other, the conductor layer 40 and the plating layer 60 may be integrated together.

In (f) of FIG. 2, the resist pattern 32 that is the photocured portion is peeled off and removed using a strongly alkaline aqueous solution. The strongly alkaline developer may be, for example, a 1% to 10% by mass aqueous sodium hydroxide solution or a 1% to 10% by mass aqueous potassium hydroxide solution. Next, the conductor layer 40 masked by the resist pattern 32 is removed by a flash etching process to form a conductor pattern 70 including a plating layer after etching process 62 and a conductor layer after etching process 42. The etching solution is appropriately selected depending on the kind of the conductor layer 40, and for example, a cupric chloride solution, a ferric chloride solution, an alkaline etching solution, or a hydrogen peroxide etching solution may be used. In FIG. 2, the projection exposure method is described, but the resist pattern 32 may be formed by using a mask exposure method and an LDI exposure method together. By using the photosensitive element according to the present embodiment, a circuit board having a fine conductor pattern can be produced.

Suitable embodiments of the present disclosure have been described above, but the present disclosure is not limited to the above-described embodiments at all.

### EXAMPLES

Hereinafter, the present disclosure will be described more specifically with reference to Examples, but the present disclosure is not limited to these Examples.

### <Synthesis of Component (A)>

A solution (a) was prepared by mixing 27 parts by mass of methacrylic acid, 50 parts by mass of styrene, 3 parts by mass of 2-hydroxyethyl methacrylate, and 20 parts by mass of benzyl methacrylate together with 0.9 parts by mass of azobisisobutyronitrile. A solution (b) was prepared by dissolving 0.5 parts by mass of azobisisobutyronitrile in 50 parts by mass of a liquid mixture (x) of 30 parts by mass of 1-methoxy-2-propanol and 20 parts by mass of toluene. In a flask equipped with a stirrer, a reflux condenser, a thermometer, a dropping funnel, and a nitrogen gas introducing tube, 500 g of the liquid mixture (x) was charged, and then stirred while nitrogen gas was blown into the flask, and the temperature was raised to 80° C. The solution (a) was added dropwise to the mixture in the flask at a constant dropping rate over 4 hours, and then stirring was performed at 80° C. for 2 hours. Next, the solution (b) was added dropwise to the solution in the flask at a constant dropping rate over 10 minutes, and then the solution in the flask was stirred at 80° C. for 3 hours. Furthermore, the solution in the flask was heated to 90° C. for 30 minutes and kept at 90° C. for 2 hours, then stirring was stopped, and cooling to room temperature (25° C.) was performed to obtain a solution of binder polymer A1. The non-volatile components (solids) in the solution of binder polymer A1 accounted for 49.8% by mass. The weight average molecular weight of the binder polymer A1 was 35000.

The weight average molecular weight was determined by performing measurement by gel permeation chromatography (GPC) and conversion using the calibration curve of standard polystyrene. The conditions for GPC are shown as follows.

### (Conditions for GPC)

Pump: Hitachi Model L-6000 (trade name, manufactured by Hitachi, Ltd.)
Columns: The following three in total
   Gelpack GL-R420
   Gelpack GL-R430
   Gelpack GL-R440 (all trade names, manufactured by Resonac Corporation)
Eluent: Tetrahydrofuran
Measurement temperature: 40° C.
Flow rate: 2.05 mL/min
Detector: Hitachi Model L-3300 RI (trade name, manufactured by Hitachi, Ltd.)

### <Preparation of Photosensitive Resin Composition>

Each of the photosensitive resin compositions was prepared by mixing the respective components shown in Tables 1 and 2 in the blending amounts (parts by mass) shown in the same tables. The blending amounts (parts by mass) of components other than the solvent shown in Tables 1 and 2 are the masses of non-volatile components (solid amounts). Details of the respective components in Tables 1 and 2 are shown as follows.

### (Binder Polymer)

A1: Binder polymer A1 synthesized above

### (Photopolymerizable Compound)

FA-321M (70): 70% Solution of 2,2-bis(4-(methacryloxyethoxy)phenyl)propane (adduct of 10 moles of ethylene oxide on average) in propylene glycol monomethyl ether (manufactured by Resonac Corporation)
FA-024M: (PO)(EO)(PO)-Modified dimethacrylate (manufactured by Resonac Corporation, adduct of 6 moles of ethylene oxide and 12 moles of propylene oxide on average (total value))
BP-2EM: 2,2-Bis (4-(methacryloxypolyethoxy)phenyl)propane (manufactured by Kyoeisha Chemical Co., Ltd., EO group: 5.2 (total value))
   (Photopolymerization initiator)
B-CIM: 2,2′-Bis (o-chlorophenyl)-4,4′,5,5′-tetraphenyl-1,2′-biimidazole (manufactured by Hampford Research Inc.)
TR-HABI-102:2,2′,4-Tris-(o-chlorophenyl)-5-(3,4-dimethoxyphenyl)-4′,5′-diphenylbiimidazole (trade name, manufactured by Changzhou Tronly New Electronic Materials Co., Ltd.)
OXE-01: 1,2-Octanedione-1-[4-(phenylthio)phenyl]-2-(o-benzoyloxime) (manufactured by BASF Japan Ltd., trade name: IRGACURE OXE-01)

### (Photosensitizer)

DBA: 9,10-Dibutoxyanthracene (manufactured by Kawasaki Kasei Chemicals Ltd.)

### (Polymerization Inhibitor)

TBC: 4-t-Butylcatechol (manufactured by DIC Corporation, trade name “DIC-TBC”)

### (Dye)·

LCV: Leuco Crystal Violet (manufactured by Yamada Chemical Co., Ltd.)
MKG: Malachite Green (manufactured by OSAKA ORGANIC CHEMICAL INDUSTRY LTD.)

### (Solvent)

Cyclopentanone (HSP value: 7.3)
Cyclohexanone (HSP value: 5.2)
Anisole (HSP value: 6.7)
Toluene (HSP value: 5.6)
MEK: Methyl ethyl ketone (HSP value: 7.9)
MFG: 1-Methoxy-2-propanol (HSP value: 12.6)
PGMEA: Propylene glycol 1-monomethyl ether 2-acetate (HSP value: 11.2)
Mesitylene (HSP value: 6.3)
Acetone (HSP value: 10.2)
Methanol (HSP value: 23.7)

The HSP value (Hansen solubility parameter) referred to here is the distance (Ra) between the HSP values (δD₁, δP₁, δH₁) of the 2-(o-chlorophenyl)-4,5-diphenylimidazole structure in B-CIM and the HSP values (δD₂, δP₂, δH₂) of the solvent, and was calculated by the following equation. In the equation, δD represents the energy derived from dispersion forces between molecules, δP represents the energy derived from dipolar intermolecular forces between molecules, and δH represents the energy derived from hydrogen bonding forces between molecules.

$$Ra = \sqrt{4 {( δ {D}_{2} - δ {D}_{1} )}^{2} + {( δ {P}_{2} - δ {P}_{1} )}^{2} + {( δ {H}_{2} - δ {H}_{1} )}^{2}} \qquad [ Math . 1 ]$$

### <Evaluation of Photosensitive Resin Composition>

### (Discoloration Resistance)

The photosensitive resin compositions of Examples 1 to 9 and Comparative Examples 1 to 5 were each transferred to a plastic bottle, then the sealed plastic bottle was stored for 7 days under storage conditions of a temperature of 20° C. and a humidity of 60% RH in a completely light-shielded state. The change in color of the photosensitive resin composition after 7 days of storage was visually observed, and the discoloration resistance was evaluated according to the following criteria.
A: Discoloration was not observed even after 7 days of storage.
B: Slight discoloration was observed after 7 days of storage.
C: Remarkable discoloration was observed after 7 days of storage.

TABLE 1

| | Example | | | | | | | | |
|---|---|---|---|---|---|---|---|---|---|
| | 1 | 2 | 3 | 4 | 5 | 6 | 7 | 8 | 9 |
| A1 | 56 | 56 | 56 | 56 | 56 | 56 | 56 | 56 | 56 |
| FA-321M (70) | 35 | 35 | 35 | 35 | 35 | 35 | 35 | 35 | 35 |
| FA-024M | 4 | 4 | 4 | 4 | 4 | 4 | 4 | 4 | 4 |
| BP-2EM | 5 | 5 | 5 | 5 | 5 | 5 | 5 | 5 | 5 |
| B-CIM | 8 | 8 | 8 | 8 | 8 | 8 | 8 | — | — |
| TR-HABI-102 | — | — | — | — | — | — | — | 8 | — |
| OXE-01 | — | — | — | — | — | — | — | — | 8 |
| DBA | 0.65 | 0.65 | 0.65 | 0.65 | 0.65 | 0.65 | 0.65 | — | — |
| TBC | 0.02 | 0.02 | 0.02 | 0.02 | 0.02 | 0.02 | 0.02 | 0.02 | 0.02 |
| LCV | 0.5 | 0.5 | 0.5 | 0.5 | 0.5 | 0.5 | 0.5 | 0.5 | 0.5 |
| MKG | 0.02 | 0.02 | 0.02 | 0.02 | 0.02 | 0.02 | 0.02 | 0.02 | 0.02 |
| Cyclopentanone | 21 | 29 | 36 | — | — | — | — | 21 | 21 |
| Cyclohexanone | — | — | — | 21 | 29 | 36 | — | — | — |
| Anisole | — | — | — | — | — | — | 21 | — | — |
| Acetone | 8 | — | — | 8 | — | — | 8 | 8 | 8 |
| Methanol | 7 | 7 | — | 7 | 7 | — | 7 | 7 | 7 |
| Discoloration | A | A | A | A | A | A | B | A | A |
| resistance | | | | | | | | | |

TABLE 2

| | Comparative Example | | | | |
|---|---|---|---|---|---|
| | 1 | 2 | 3 | 4 | 5 |
| A1 | 56 | 56 | 56 | 56 | 56 |
| FA-321M (70) | 35 | 35 | 35 | 35 | 35 |
| FA-024M | 4 | 4 | 4 | 4 | 4 |
| BP-2EM | 5 | 5 | 5 | 5 | 5 |
| B-CIM | 8 | 8 | 8 | 8 | 8 |
| DBA | 0.65 | 0.65 | 0.65 | 0.65 | 0.65 |
| TBC | 0.02 | 0.02 | 0.02 | 0.02 | 0.02 |
| LCV | 0.5 | 0.5 | 0.5 | 0.5 | 0.5 |
| MKG | 0.02 | 0.02 | 0.02 | 0.02 | 0.02 |
| Toluene | 21 | — | — | — | — |
| MEK | — | 21 | — | — | — |
| MFG | — | — | 21 | — | — |
| PGMEA | — | — | — | 21 | — |
| Mesitylene | — | — | — | — | 21 |
| Acetone | 8 | 8 | 8 | 8 | 8 |
| Methanol | 7 | 7 | 7 | 7 | 7 |
| Discoloration resistance | C | C | C | C | C |

Reference Signs List

1: photosensitive element, 2, 20: support, 3, 30: photosensitive
layer, 4: protective layer, 32: resist pattern, 40: conductor layer, 42:
conductor layer after etching process, 50: insulating layer, 60: plating
layer, 62: plating layer after etching process, 70: conductor pattern, 80:
actinic light.

1. A photosensitive resin composition comprising: a binder polymer, a photopolymerizable compound, a photopolymerization initiator, and a solvent, wherein
the solvent includes at least one selected from the group consisting of a ketone-based solvent having an alicyclic skeleton and an aromatic ether-based solvent.

2. The photosensitive resin composition according to claim 1, wherein the ketone-based solvent having an alicyclic skeleton includes at least one selected from the group consisting of cyclopentanone and cyclohexanone.

3. The photosensitive resin composition according to claim 1, wherein the aromatic ether-based solvent includes anisole.

4. The photosensitive resin composition according to claim 1, wherein the solvent does not include toluene.

5. A photosensitive element comprising:
a support; and
a photosensitive layer formed on the support using the photosensitive resin composition according to claim 1.

6. A method for forming a resist pattern, the method comprising:
a step of forming a photosensitive layer on a substrate using the photosensitive resin composition according to claim 1;
a step of photocuring a portion of the photosensitive layer; and
a step of removing an uncured portion of the photosensitive layer by development.

7. The method for forming a resist pattern according to claim 6, wherein an inorganic alkaline developer is used in the development.

8. A method for forming a resist pattern, the method comprising:
a step of forming a photosensitive layer on a substrate using the photosensitive element according to claim 5;
a step of photocuring a portion of the photosensitive layer; and
a step of removing an uncured portion of the photosensitive layer by development.

9. The method for forming a resist pattern according to claim 8, wherein an inorganic alkaline developer is used in the development.

10. A method for manufacturing a circuit board, the method comprising a step of forming a conductor pattern by etching or plating a substrate on which a resist pattern is formed by the method for forming a resist pattern according to claim 6.

11. A method for manufacturing a circuit board, the method comprising a step of forming a conductor pattern by etching or plating a substrate on which a resist pattern is formed by the method for forming a resist pattern according to claim 8.
